(19) United States
(12) Patent Application Publication
(10) Pub. No.: US 2010/0148199 A1
(43) Pub. Date: Jun. 17, 2010

(54) Light emitting device with fine pattern

(75) Inventors: Jong Kyu Kim, Watervliet, NY (US); Frank W. Mont, Poughkeepsie, NY (US); Ahmed N. Noemaun, Troy, NY (US); David J. Poxson, Troy, NY (US); E. Fred Schubert, Troy, NY (US); Hyunsoo Kim, Suwon (KR); Cheolsoo Sone, Anyang (KR)

Correspondence Address: STAAS & HALSEY LLP, SUITE 700, 1201 NEW YORK AVENUE, N.W., WASHINGTON, DC, 20005, US

(73) Assignees: SAMSUNG LED CO., LTD., Suwon (KR); RENSSELAER POLYTECHNIC INSTITUTE, Troy, NY (US)

(21) Appl. No.: 12/591,011

(22) Filed: Nov. 4, 2009

Related U.S. Application Data
(60) Provisional application No. 61/111,177, filed on Nov. 4, 2008.

(51) Int. Cl. H01L 33/00

(52) U.S. Cl. 257/98; 257/103; 257/E33.067

(57) ABSTRACT

A semiconductor light emitting device includes a semiconductor light emitting structure including first and second conductivity type semiconductor layers, and an active layer disposed therebetween, first and second electrodes connected to the first and second conductivity type semiconductor layers, respectively, and a fine pattern for light extraction, formed on a light emitting surface from which light generated from the active layer is emitted. The fine pattern for light extraction is formed as a graded refractive index layer having a refractive index which decreases with vertical distance from the light emitting surface.

### CROSS-REFERENCE TO RELATED APPLICATIONS

The present application claims priority to U.S. Provisional Patent Application 61/111,177, filed Nov. 4, 2008, the disclosure of which is hereby incorporated by reference.

### BACKGROUND OF THE INVENTION

1. Field of the Invention

The present invention relates to a semiconductor light emitting device, and more particularly, to a semiconductor light emitting device having a fine pattern to enhance light extraction efficiency.

2. Description of the Related Art

In general, semiconductor light emitting diodes (LEDs) are in wide use as light sources for full-color displays, image scanners, various signal systems and optical communications devices. Semiconductor LEDs emit light generated from active layers using the principle of electron-hole recombination. In particular, nitride semiconductors are currently drawing a great deal of attention as the constituents of light emitting devices, which are able to cover a wide wavelength range, including blue light and green light ranges according to the composition ratio thereof.

The light efficiency of such semiconductor light emitting devices is determined by internal quantum efficiency and light extraction efficiency, which is also referred to as “external quantum efficiency”. In particular, the light extraction efficiency is significantly affected by the optical properties of light emitting devices, that is, the refractive index of each structure and/or the flatness of interfaces.

However, nitride semiconductor light emitting devices have fundamental limitations in terms of light extraction efficiency.

A semiconductor layer constituting a semiconductor light emitting device has a greater refractive index than that of the outside atmosphere or a substrate, thus reducing a critical angle that decides the angular range of incidence of light. As a result, a considerable fraction of the light generated from an active layer is totally reflected internally, thus traveling in an undesired direction or being lost in total reflection. This inevitably impairs light extraction efficiency.

In detail, in nitride semiconductor light emitting devices, the refractive index of GaN is 2.4. Therefore, when falling onto the GaN-atmosphere interface at a greater angle of incidence than 23.6°, the critical angle, light generated from an active layer is totally reflected internally and travels in a lateral direction, thus being lost or failing to travel in a desired direction. For this reason, actual light extraction efficiency is a mere 13% or so. Similarly, a sapphire substrate having a refractive index of 1.78 causes low light extraction efficiency, that is, low external quantum efficiency, at the sapphire-atmosphere interface. This low external quantum efficiency adversely affects the light emission efficiency of a semiconductor light emitting device to a significant extent. Therefore, the need has arisen to make structural improvements in semiconductor light emitting devices.

### SUMMARY OF THE INVENTION

An aspect of the present invention provides a structurally improved semiconductor light emitting device to reduce total internal reflection resulting from different refractive indices between the semiconductor light emitting device and the atmosphere or an encapsulating material at the time of light extraction, and to enhance light transmission efficiency.

According to an aspect of the present invention, there is provided a semiconductor light emitting device including: a semiconductor light emitting structure including first and second conductivity type semiconductor layers, and an active layer disposed therebetween; first and second electrodes connected to the first and second conductivity type semiconductor layers, respectively; and a fine pattern for light extraction, formed on a light emitting surface from which light generated from the active layer is emitted. The fine pattern for light extraction is formed as a graded refractive index layer having a refractive index which decreases with vertical distance from the light emitting surface.

The fine pattern for light extraction may be formed of at least one selected from the group consisting of TiO₂, SiC, GaN, GaP, SiNx, ZrO₂, ITO, AlN, Al₂O₃, MgO, SiO₂, CaF₂ and MgF₂.

The fine pattern for light extraction may include: a first material layer disposed on the second conductivity type semiconductor layer and having a first refractive index; and a second material layer disposed on the first material layer and having a second refractive index less than the first refractive index.

The first refractive index may be equal to or less than a refractive index of the second conductivity type semiconductor layer.

The semiconductor light emitting device may further include a transparent electrode layer disposed between the second conductivity type semiconductor layer and the fine pattern for light extraction. In this case, the first refractive index may be equal to or less than a refractive index of the transparent electrode layer.

The fine pattern for light extraction may have a multilayer structure of three layers or more, which further includes at least one third material layer disposed between the first and second material layers and having a refractive index ranging between the first and second refractive indices.

The third material layer may have a composition of (a composition of the first material layer)₁₋ₓ (a composition of the second material layer)ₓ, where 0<x<1.

The fine pattern for light extraction may further include a third material layer disposed between the first and second material layers and having a refractive index which decreases gradually with vertical distance from the first material layer toward the second material layer, within a range of the first refractive index to the second refractive index.

The third material layer may have a composition of (a composition of the first material layer)₁₋ₓ (a composition of the second material layer)ₓ where 0<x<1, and a value of x may increase with vertical distance from the first material layer toward the second material layer.

The first and second material layers may be formed of TiO₂ and SiO₂, respectively, and the third material layer may be formed of TiO₂—SiO₂. Alternatively, the first and second material layers may be formed of ITO and SiO₂, respectively, and the third material layer may be formed of ITO—SiO₂.

The fine pattern for light extraction may have a height and width falling within the range of 0.1 μm to 5 μm. The fine pattern for light extraction may have an aspect ratio of higher than 0.1.

The fine pattern for light extraction may have various shapes, and may have a rough hemispherical shape.

The semiconductor light emitting device may further include a transparent encapsulating material layer covering at least the light emitting surface on which the fine pattern for light extraction is disposed. The encapsulating material layer may have a refractive index which is equal to or less than that of the second material layer.

The semiconductor light emitting structure may include a nitride semiconductor layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view showing a semiconductor light emitting device according to an exemplary embodiment of the present invention;

FIGS. 2A and 2B are graphs illustrating enhancement effects in the light transmittance and reflectivity of a graded refractive index layer having a multilayer structure, respectively;

FIGS. 3A through 3C are schematic views illustrating enhancement effects in light extraction efficiency by use of a fine pattern;

FIG. 4 is a graph showing light extraction efficiency according to the number of layers of a graded refractive index layer having a multilayer structure;

FIG. 5 is a cross-sectional view showing a semiconductor light emitting device according to another exemplary embodiment of the present invention;

FIG. 6 is a graph showing optical outputs over forward current, regarding the LED samples produced according to the embodiments 1A through 1D and the comparative example 1;

FIG. 7 is a graph comparing the optical outputs of the LED samples produced according to the embodiment 2 of the present invention and the comparative example 2;

FIG. 8 is a graph comparing the light extraction efficiency of an LED sample produced according to embodiment 3 of the present invention and LED samples produced according to comparative examples 3A and 3B; and

FIG. 9 is a graph comparing the light extraction efficiency of LED samples produced according to embodiments 4A and 4B of the present invention.

### DETAILED DESCRIPTION OF THE PREFERRED EMBODIMENT

Exemplary embodiments of the present invention will now be described in detail with reference to the accompanying drawings.

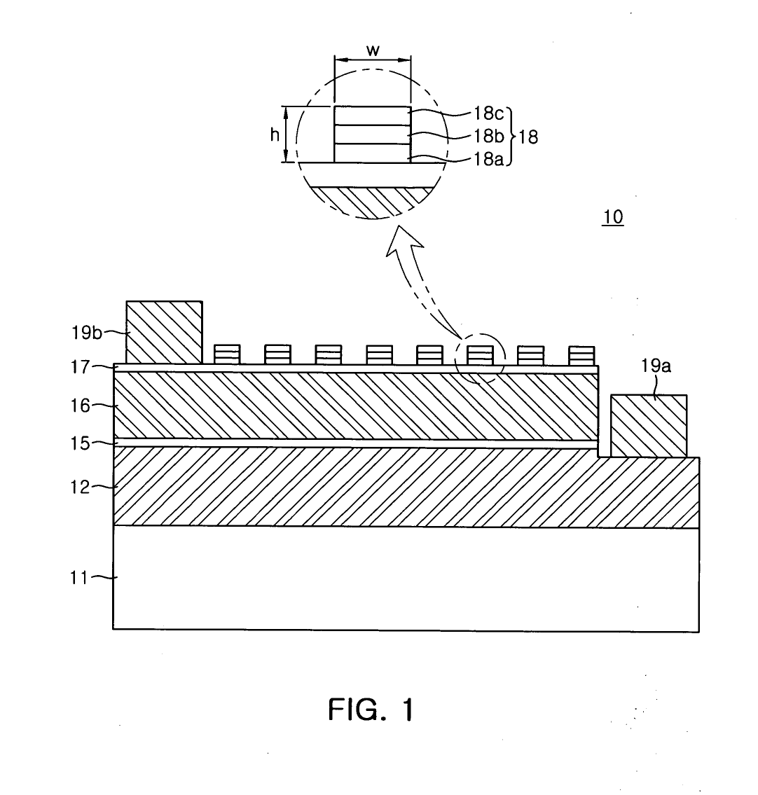

FIG. 1 is a cross-sectional view of a semiconductor light emitting device according to an exemplary embodiment of the present invention.

As shown in FIG. 1, a semiconductor light emitting device 10 according to this embodiment includes a semiconductor light emitting structure formed on the substrate 11. The semiconductor light emitting structure includes first and second conductivity type semiconductor layers 12 and 16, and an active layer 15 disposed therebetween.

The first conductivity type semiconductor layer 12 may utilize a group III-V nitride semiconductor material, for example, an n-GaN layer. The second conductivity type semiconductor layer 16 may be a group III-V nitride semiconductor layer, for example, a p-GaN layer or a p-GaN/AlGaN layer.

The active layer 15 may be a GaN-based group III-V nitride semiconductor layer having a composition of InₓAl_{y}Ga_{1-x-y}N where 0≦x<1, 0≦y<1 and 0≦x+y<1. The active layer 15 may be a multi-quantum well (hereinafter, referred to as ‘MQW’), or a single quantum well. The active layer 15 may have a structure of GaN/InGaN/GaN MQW or GaN/AlGaN/GaN MQW.

First and second electrodes 19a and 19b are formed on, and are connected to the first and second conductivity type semiconductor layers 12 and 16, respectively. The first electrode 19a and the second electrode 19b may be formed of a metallic material such as Au, Al or Ag, or a transparent conductive material, and may have a multilayer structure of two layers or more.

According to this embodiment, a transparent electrode layer 17 may be disposed on the second conductivity type semiconductor layer 16. The transparent electrode layer 17 may be formed of a transparent conductive oxide. For example, the material of the transparent electrode layer 17 may be at least one selected from the group consisting of indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminium-doped zinc oxide (AZO), gallium-doped zinc oxide (GZO), In₄Sn₃O₁₂, and Zinc Magnesium Oxide (Zn₍₁₋ₓ₎MgₓO where 0≦x≦1). A specific example thereof may include Zn₂In₂O₅, GaInO₃, ZnSnO₃, F-doped SnO₂, Al-doped ZnO, Ga-doped ZnO, MgO, ZnO, or the like.

In the semiconductor light emitting device, when a predetermined voltage is applied between the first electrode 19a and the second electrode 19b, electrons and holes are injected to the active layer 15 from the first conductivity type semiconductor layer 12 and the second conductivity type semiconductor layer 16, respectively, and are recombined in the active layer 15. Thus, light can be generated from the active layer 15.

Fine patterns 18 for light extraction (hereinafter, also referred to as “fine patterns”) are formed on a light emitting surface of the semiconductor light emitting device 10. The light emitting surface refers to the specific surface of the semiconductor light emitting device 10 from which light from the active layer 15 is emitted.

The fine patterns 18 each are configured as a graded refractive index layer having a refractive index which decreases with vertical distance from the light emitting surface. In a specific example, the fine pattern 18 may include at least two material layers having different refractive indices. According to this embodiment, the fine pattern 18 is illustrated as having three material layers.

The material of each of the material layers, although not limited, may be one selected from the group consisting of TiO₂, SiC, GaN, GaP, SiNₓ, ZrO₂, ITO, Al_{N}, Al₂O₃, MgO, SiO₂, CaF₂ and MgF₂ to meet the condition regarding the graded refractive index of the fine pattern 18. Each of the material layers may be formed by sputtering or evaporation.

According to this embodiment, the fine pattern 18 includes a first material layer 18a having a first refractive index, a second material layer 18c having a second refractive index less than the first refractive index, and a third material layer 18b additionally provided between the first and second material layers 18a and 18c and having a refractive index ranging between the first and second refractive indices. Also, the third material layer 18b may have a composition of (the composition of the first material layer)₁₋ₓ (the composition of the second material layer)ₓ where 0<x<1.

Alternatively, the third material layer 18b between the first and second material layers 18a and 18c may be a material layer having a refractive index which decreases gradually with vertical distance from the first material layer 18a toward the second material layer 18b, within the range of the first refractive index and the second refractive index. The third material layer 18b may have a composition of (the composition of the first material layer)₁₋ₓ (the composition of the second material layer)ₓ where 0<x<1 and the value of ‘x’ may increase with vertical distance from the first material layer 18a toward the second material layer 18c.

In a specific example, the first and second material layers 18a and 18c may be formed of TiO₂ and SiO₂, respectively, and the third material layer 18b may be formed of TiO₂—SiO₂. In another example, the first and second material layers 18a and 18c may be formed of ITO and SiO₂, respectively, and the third material layer 18b may be formed of ITO—SiO₂. As described above, the third material layer 18b may be formed of TiO₂—SiO₂ or ITO—SiO₂ in which the ratio of SiO₂ increases gradually with proximity to the second material layer 18c.

The first refractive index of the first material layer 18a is equal to or less than the refractive index of a material constituting the light emitting surface. For example, according to this embodiment, the first refractive index of the first material layer 18a may be equal to or less than the refractive index of the transparent electrode layer 17.

According to this embodiment, the fine pattern 18 is formed on the transparent electrode layer 17. Alternatively, in the case that the transparent electrode layer is absent, the fine pattern 18 may be formed directly on the second conductivity type semiconductor layer 16.

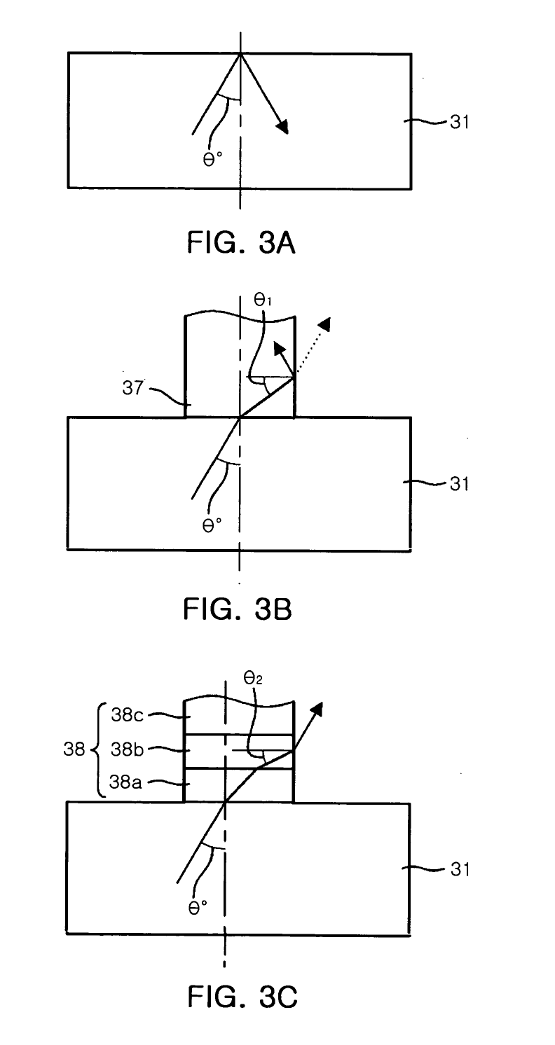

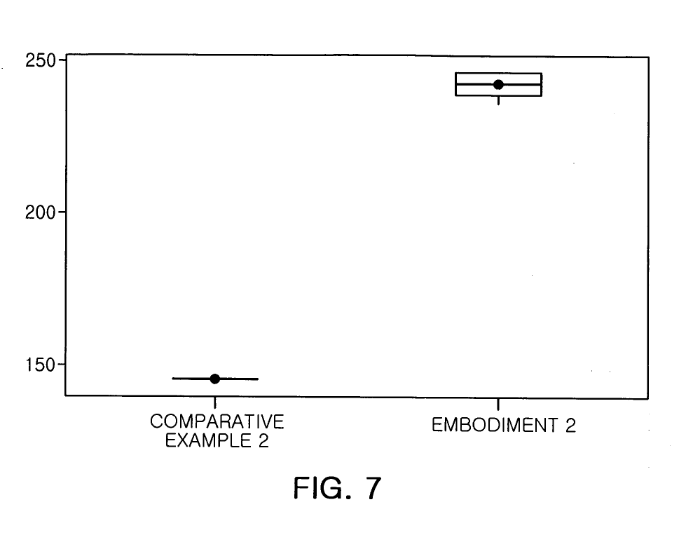

The height and width of the fine pattern 18, although not limited, may fall within the range of 0.1 μm to 5 μm. With respect to the fine pattern employed in this embodiment, light extraction through the side surface of the fine pattern may be considered important. In this case, the desirable aspect ratio of the fine pattern may be suggested. This will be described with reference to FIG. 3 and embodiment 1 depicted in FIG. 7.

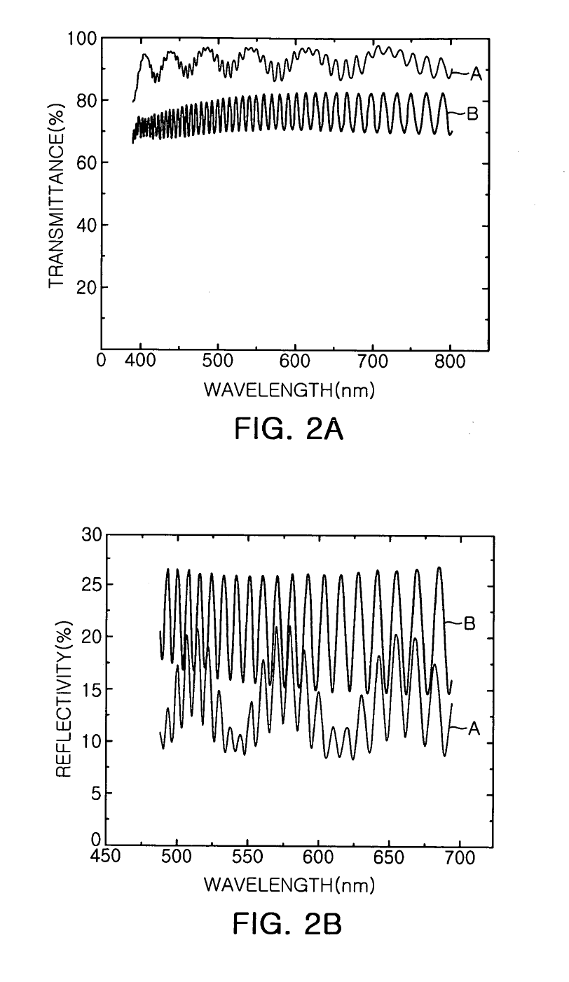

FIGS. 2A and 2B are graphs illustrating enhancements in the light transmittance and reflectivity of a graded refractive index layer having a multilayer structure.

For the graphs of FIGS. 2A and 2B, light transmittance and reflectivity are measured at the GaN surface of a sapphire substrate/GaN structure indicated by ‘B’ in FIGS. 2A and 2B. Light transmittance and reflectivity are also measured at the light emitting surface of a sapphire substrate/GaN/graded refractive index layer structure, indicated by ‘A’ in FIGS. 2A and 2B and employing a graded refractive index layer according to the present invention. The graphs of FIGS. 2A and 2B illustrate the results of comparison between the structures ‘A’ and ‘B’.

The graded refractive index layer has a multilayer structure of sequentially laminated TiO₂/(TiO₂)ₓ(SiO₂)₁₋ₓ/SiO₂. In the case of a light wavelength of 550 nm, the layer of TiO₂ has a refractive index of about 2.3 which is less than 2.5, the refractive index of GaN, and the layer of SiO₂ has a relatively low refractive index of about 1.44. The layer of (TiO₂)ₓ(SiO₂)₁₋ₓ, where 0<x<1, is formed with a refractive index that decreases gradually within the range of 2.3 to 1.44 according to the value of ‘x’. That is, in the layer of (TiO₂)ₓ(SiO₂)₁₋ₓ, where 0<x<1, the refractive index decreases gradually due to the composition ratio of SiO₂ increasing with proximity to the layer of SiO₂.

Referring to FIGS. 2A and 2B, the graded refractive index layer, according to the present invention, ensures high light transmittance and low reflectivity, thereby enhancing light extraction efficiency.

According to the present invention, the graded refractive index layer is provided as a fine pattern on the light emitting surface of a light emitting device. Unlike general fine patterns, the fine pattern in the present invention allows for graded refractive index distribution, thereby allowing for significant enhancement in the light extraction efficiency through the side surface thereof. This will now be described with reference to FIGS. 3A through 3C.

A high-refractive-index structure 31 depicted in FIG. 3A may be understood as a light emitting device without a fine pattern. As indicated by an arrow, the critical angle for light extraction is excessively low due to a significant difference in the refractive index. Incident beams, having an angle greater than the critical angle, are totally reflected internally, impairing light extraction efficiency to a significant extent.

Referring to FIG. 3B, if a pattern 37 having a medium refractive index is used, the difference in the refractive index at the interface may be reduced, thus increasing the critical angle. Accordingly, an enhancement of light extraction efficiency can be anticipated.

Similarly, referring to FIG. 3C, a graded refractive index layer 38, including three material layers 38a, 38b and 38c, can also enhance light extraction efficiency due to its refractive index which decreases gradually at the interfaces. In comparison with FIG. 3B, beams fall onto the side surface of a pattern depicted in FIG. 3C at a lower angle of incidence after passing through the interfaces, thus they are likely to be extracted without being totally reflected. For this reason, by using the fine pattern employing a graded refractive index layer, light extraction efficiency can be expected to improve considerably.

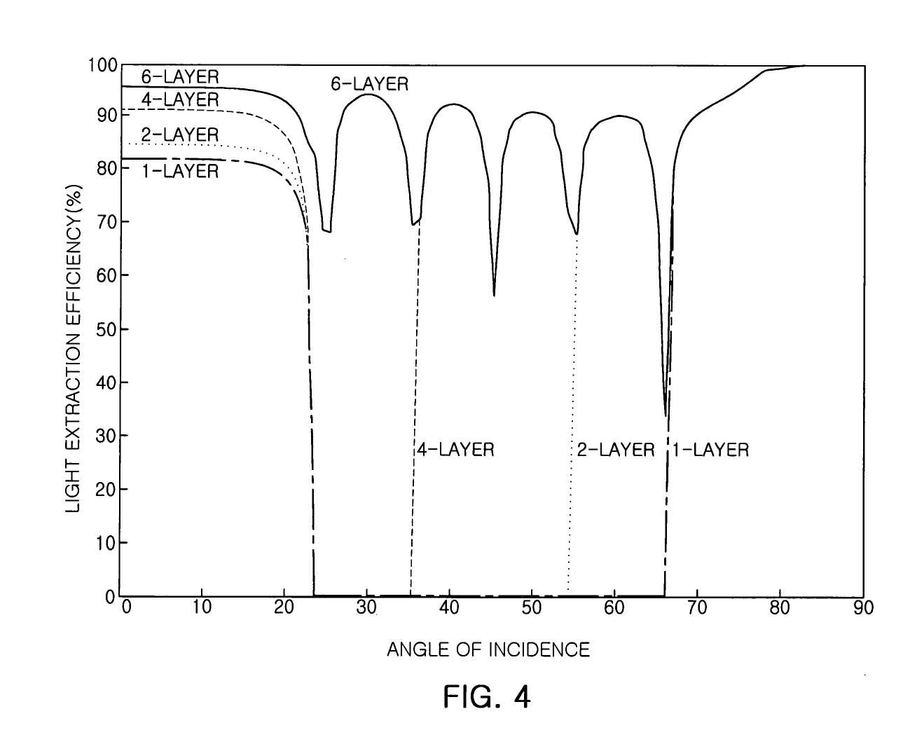

Enhancements in light extraction by use of the fine pattern employing the graded refractive index layer may be confirmed through the experimental results depicted in FIG. 4.

As shown in FIG. 4, a single-layer pattern corresponding to FIG. 3B may be expected to achieve light extraction efficiency of higher than 80% when an angle of incidence is 65° or greater. However, the angle of incidence decreases with an increase in the number of layers (55° in the case of two layers, and 35° in the case of four layers). A pattern with six layers may be expected to achieve relatively high light extraction efficiency at almost every angle of incidence.

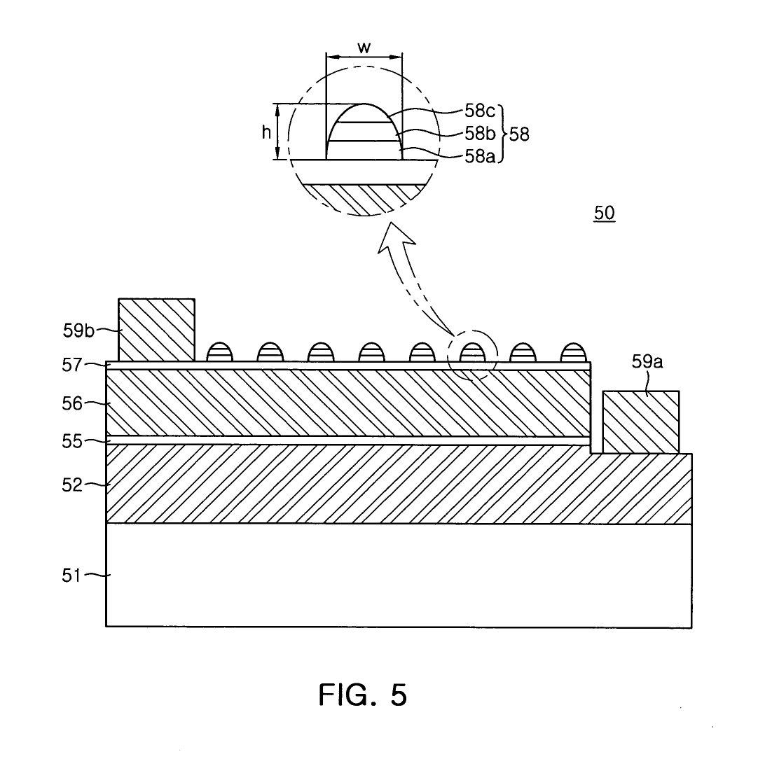

FIG. 5 is a cross-sectional view showing a semiconductor light emitting device according to another exemplary embodiment of the present invention.

Referring to FIG. 5, a semiconductor light emitting device 50, according to this embodiment, includes a semiconductor light emitting structure on a substrate 51. The semiconductor light emitting structure includes first and second conductivity type semiconductor layers 52 and 56, and an active layer 55 disposed therebetween. First and second electrodes 59a and 59b are formed on, and are connected to the first and second conductivity type semiconductor layers 52 and 56, respectively.

Similar to the previous embodiment, the first and second conductivity type semiconductor layers 52 and 56 may be formed of a group III-nitride semiconductor material. The active layer 55 may be a GaN-based group III-V nitride semiconductor layer having a composition of InₓAl_{y}Ga_{1-x-y}N where 0≦x<1, 0≦y<1 and 0≦x+y<1. The active layer 55 may have a GaN/InGaN/GaN MQW structure or a GaN/AlGaN/GaN MQW structure.

According to this embodiment, a transparent electrode layer 57 may be disposed on the second conductivity type semiconductor layer 56. The transparent electrode layer 57 may be formed of a transparent conductive oxide.

Fine patterns 58 for light extraction are disposed on the light emitting surface of a semiconductor light emitting device 50. The fine patterns 58 each are formed as a graded refractive index layer having a refractive index which decreases with vertical distance from the light emitting surface. In a specific example, the fine pattern 58 may include at least two material layers having different refractive indices. According to this embodiment, the fine pattern 58 includes three material layers, similar to the fine pattern 18 depicted in FIG. 1.

Unlike the fine pattern 18 depicted in FIG. 1, the fine pattern 58 employed in this embodiment is provided as a rough hemispherical pattern. The hemispherical pattern may be obtained by forming a hemispherical pattern of a photosensitive material using thermal processing, and performing dry etching thereupon. This hemispherical fine pattern 58 has a curved surface, so that the extraction efficiency of light traveling into the atmosphere or an encapsulating material layer can be improved significantly.

The shape of the fine pattern applicable to the present invention is not limited to the description. For example, the fine pattern may have various plane shapes such as a circle, an oval or a polygon.

The fine pattern 58 depicted in FIG. 5 includes a first material layer 58a having a first refractive index, a second material layer 58c having a second refractive index less than the first refractive index, and a third material layer 58b additionally provided between the first and second material layers 58a and 58c and having a refractive index ranging between the first and second refractive indices. The third material layer 58b may have a composition of (the composition of the first material layer)₁₋ₓ (the composition of the second material layer)ₓ, where 0<x<1.

The third material layer 58b may have a refractive index which decreases with vertical distance from the first material layer 58a toward the second material layer 58b within the range of the first refractive index and the second refractive index. The third material layer 58b may have a composition of (the composition of the first material layer)₁₋ₓ (the composition of the second material layer)ₓ where 0<x<1 and the value of ‘x’ increases with vertical distance from the first material layer 58a toward the second material layer 58b.

In a detailed example, the first and second material layers 58a and 58c may be formed of TiO₂ and SiO₂, respectively, and the third material layer 58b may be formed of TiO₂—SiO₂. In another example, the first and second material layers 58a and 58c may be formed of ITO and SiO₂, respectively, and the third material layer 58b may be formed of ITO—SiO₂. Also, the third material layer 58b may be formed of TiO₂—SiO₂ or ITO—SiO₂ in which the ratio of SiO₂ material increases with proximity to the second material layer 58c.

Hereinafter, the operation and effect of the present invention will be described in more detail using exemplary embodiments of the present invention.

### Embodiment 1

Four nitride semiconductor light emitting devices are produced. That is, an n-type GaN layer, an active layer having a InGaN/GaN MQW structure, and a p-type AlGaN/GaN layer are grown on a sapphire layer. An ITO layer having a thickness of about 200 nm is formed as a transparent electrode layer on the surface of the p-type GaN layer. Thereafter, the portion of the n-type GaN layer is exposed by mesa etching, and an n-type electrode and a p-type electrode are formed in the exposed region of the n-type GaN layer and in the region of the ITO layer, respectively.

Additionally, a fine pattern having a graded refractive index layer, proposed in the present invention, is formed on the ITO layer. This graded refractive index layer, according to this embodiment, includes the three layers of ITO/(ITO)₁₋ₓ(SiO₂)ₓ, where 0<x<1,/SiO₂, and has an overall thickness of 0.4 μm. However, the fine patterns of the four nitride semiconductor light emitting devices have different widths of 2 μm, 3 μm, 4 μm and 5 μm according to embodiments 1A, 1B, 1C and 1D of the present invention, respectively.

### Comparative Example 1

Similar to the embodiment 1, a nitride semiconductor light emitting device is produced. However, in the case of the comparative example 1, only an ITO layer of 200 nm in thickness is formed without forming a fine pattern of a graded refractive index layer.

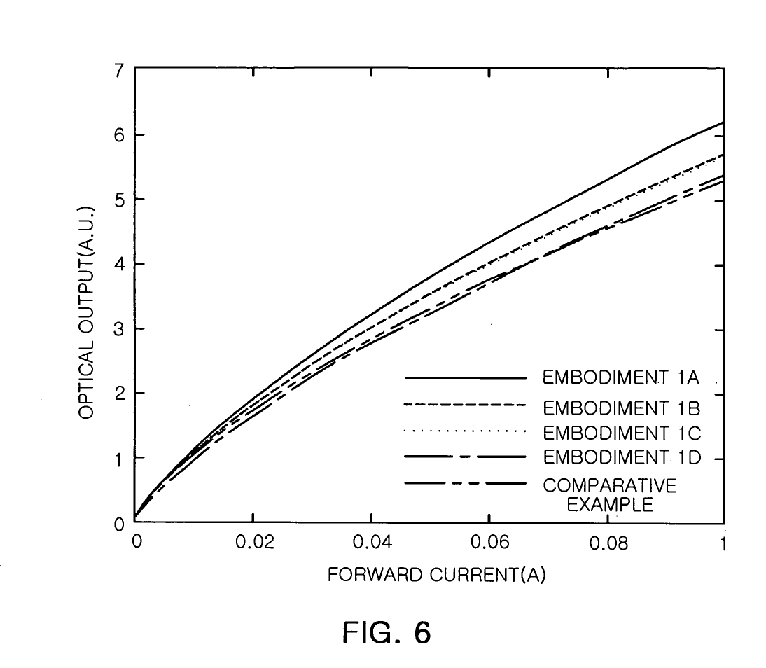

The graph of FIG. 6 shows the result of measuring optical outputs over forward current with respect to the LED samples obtained according to the comparative example 1 and the embodiments 1A through 1D. From the graph of FIG. 6, it can be seen that the enhancement effect in light extraction varies with the aspect ratios (height (h)/width (w)) of the fine patterns.

As shown in FIG. 6, in comparison with the comparative example 1, the embodiment 1D (0.4 μm/5 μm) shows a relatively small enhancement effect in light output, however, the embodiments 1B (0.4 μm/4 μm) and 1C (0.4 μm/3 μm) ensure a considerable enhancement in light output, and the embodiment 1A (0.4 μm/2 μm) achieves the highest enhancement. A fine pattern for light extraction, according to the present invention, may have a sufficiently high aspect ratio such that light can be smoothly extracted through a side surface thereof. An aspect ratio of higher than 0.1 for the fine pattern may be considered preferable based on this experiment.

### Embodiment 2

A vertical nitride semiconductor light emitting device including an InGaN/GaN active layer is produced. A fine pattern of a graded refractive index layer proposed in the present invention is formed on the surface of an n-type GaN layer. The graded refractive index layer used for this embodiment 2 has the structure of TiO₂/(TiO₂)₁₋ₓ(SiO₂)ₓ, where 0<x<1,/SiO₂, and the layer of (TiO₂)₁₋ₓ(SiO₂)ₓ, where 0<x<1 is configured with three layers such that the value of x increases upwardly. Therefore, the graded refractive index layer is provided with five layers having different refractive indices in total. The width and period of the fine pattern are designed at 2 μm, respectively.

### Comparative Example 2

A vertical nitride semiconductor light emitting device is produced in the similar manner to the embodiment 1, however a fine pattern of a graded refractive index layer is absent in this comparative example 2.

The graph of FIG. 7 shows the result of measuring optical output with respect to the LED samples obtained in the same manner as above according to the comparative example 2 and the embodiment 2. Referring to the graph of FIG. 7, it can be seen that the optical output is enhanced by about 67% in comparison with the comparative example 2.

### Embodiment 3

A vertical nitride semiconductor light emitting device including an InGaN/GaN active layer is produced. A fine pattern of a graded refractive index layer proposed in the present invention is formed on the surface of an n-type GaN layer. In this embodiment, the fine pattern has a hemispherical shape being 2 μm in diameter and 1 μm in height, at a period of 4 μm (see FIG. 5). The graded refractive index layer of the fine pattern has a refractive index distributed between 2.47 and 1.66 with vertical distance from the light emitting surface.

### Comparative Example 3

Two vertical nitride semiconductor light emitting devices are produced in the similar manner to that of the embodiment 3. Any fine pattern is not formed in one of the two vertical nitride semiconductor light emitting devices, according to comparison example 3A. In the other vertical nitride semiconductor light emitting device, a hemispherical fine pattern only including an ITO layer having a refractive index of 2 is formed with the same size and period as in the embodiment 3, according to comparative example 3B.

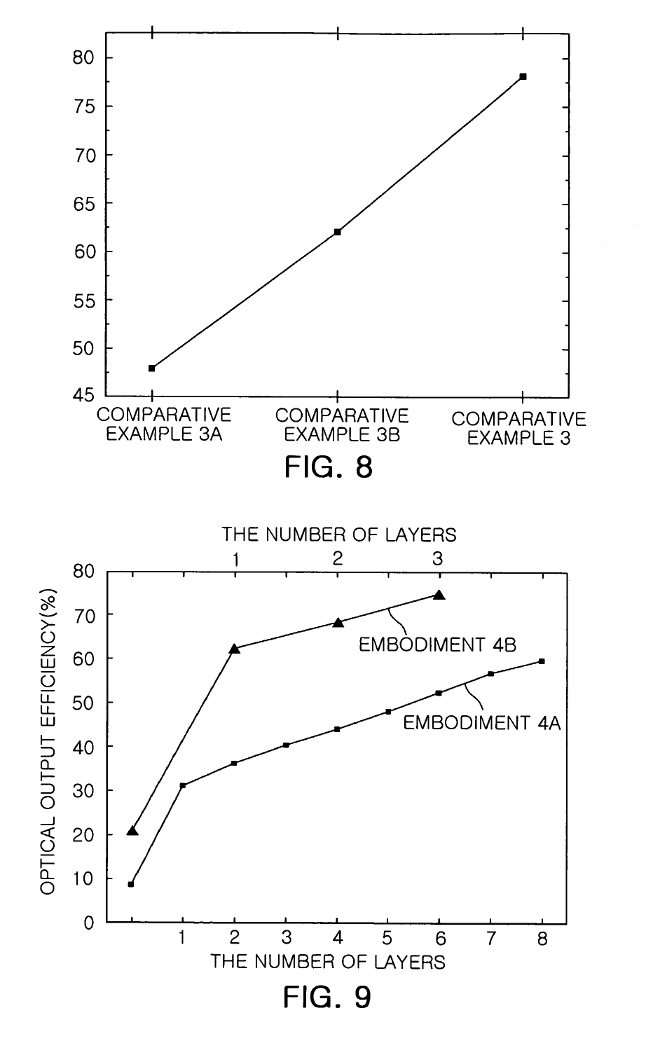

FIG. 8 is a graph comparing light extraction efficiency between an LED sample produced according to the embodiment 3 of the present invention and an LED samples produced according to the comparative examples 3A and 3B.

The LED sample corresponding to the comparison example 3A implements a light extraction efficiency of 47.9%, and the comparison example 3B implements a light extraction efficiency of 62.0%. In comparison, in the case of the embodiment 3 corresponding to the present invention, a light extraction efficiency of about 78.0% is realized, which is considerably high.

### Embodiment 4

A plurality of vertical nitride semiconductor light emitting devices, each having an InGaN/GaN active layer, are produced.

As for each vertical nitride semiconductor light emitting device of the embodiment 4, a fine pattern of a graded refractive index layer proposed in the present invention is formed on the surface of an n-type GaN layer. Here, the fine pattern has a hemispherical shape of 2 μm in width and 1 μm in height, and is formed at a period of 4 μm. The gradual change in the refractive index with vertical distance from a light emitting surface toward the top edge is controlled properly, such that structures corresponding to samples shown in the graph of FIG. 9 are produced.

One structure does not include an encapsulation material layer according to embodiment 4A, while the other structure further includes an encapsulation material layer by use of epoxy resin according to embodiment 4B.

FIG. 9 is a graph comparing light extraction efficiency between LED samples produced according to the embodiments 4A and 4B of the present invention. The significant enhancement of the light extraction efficiency is observed from the structure employing the encapsulation material layer (e.g., epoxy rein) having a less refractive index of the fine pattern.

As set forth above, according to exemplary embodiments of the invention, when light generated from an active layer of a semiconductor light emitting device is extracted, light emission efficiency can be enhanced by reducing the amount of light reflected internally due to the difference in the refractive index between the semiconductor light emitting device and the atmosphere or an encapsulating material, thus increasing light transmittance efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor light emitting device comprising:
a semiconductor light emitting structure including first and second conductivity type semiconductor layers, and an active layer disposed therebetween;
first and second electrodes connected to the first and second conductivity type semiconductor layers, respectively; and
a fine pattern for light extraction, formed on a light emitting surface from which light generated from the active layer is emitted,
wherein the fine pattern for light extraction is formed as a graded refractive index layer having a refractive index which decreases with vertical distance from the light emitting surface.

2. The semiconductor light emitting device of claim 1, wherein the fine pattern for light extraction is formed of at least one selected from the group consisting of TiO₂, SiC, GaN, GaP, SiNₓ, ZrO₂, ITO, AlN, Al₂O₃, MgO, SiO₂, CaF₂ and MgF₂.

3. The semiconductor light emitting device of claim 1, wherein the fine pattern for light extraction comprises:
a first material layer disposed on the second conductivity type semiconductor layer and having a first refractive index; and
a second material layer disposed on the first material layer and having a second refractive index less than the first refractive index.

4. The semiconductor light emitting device of claim 3, wherein the first refractive index is equal to or less than a refractive index of the second conductivity type semiconductor layer.

5. The semiconductor light emitting device of claim 3, further comprising a transparent electrode layer disposed between the second conductivity type semiconductor layer and the fine pattern for light extraction,
wherein the first refractive index is equal to or less than a refractive index of the transparent electrode layer.

6. The semiconductor light emitting device of claim 5, wherein the transparent electrode layer is a transparent conductive oxide layer.

7. The semiconductor light emitting device of claim 3, wherein the fine pattern for light extraction further comprises at least one third material layer disposed between the first and second material layers and having a refractive index ranging between the first and second refractive indices.

8. The semiconductor light emitting device of claim 7, wherein the third material layer has a composition of (a composition of the first material layer)₁₋ₓ (a composition of the second material layer)ₓ, where 0<x<1.

9. The semiconductor light emitting device of claim 3, wherein the fine pattern for light extraction further comprises a third material layer disposed between the first and second material layers and having a refractive index which decreases gradually with vertical distance from the first material layer toward the second material layer, within a range of the first refractive index to the second refractive index.

10. The semiconductor light emitting device of claim 9, wherein the third material layer has a composition of (a composition of the first material layer)₁₋ₓ (a composition of the second material layer)ₓ where 0<x<1, and a value of x increases with vertical distance from the first material layer toward the second material layer.

11. The semiconductor light emitting device of claim 10, wherein the first and second material layers are formed of TiO₂ and SiO₂, respectively, and the third material layer is formed of TiO₂—SiO₂.

12. The semiconductor light emitting device of claim 10, wherein the first and second material layers are formed of ITO and SiO₂, respectively, and the third material layer is formed of ITO—SiO₂.

13. The semiconductor light emitting device of claim 1, wherein the fine pattern for light extraction has a height and width falling within the range of 0.1 μm to 5 μm.

14. The semiconductor light emitting device of claim 13, wherein the fine pattern for light extraction has an aspect ratio of higher than 0.1.

15. The semiconductor light emitting device of claim 1, wherein the fine pattern for light extraction has a rough hemispherical shape.

16. The semiconductor light emitting device of claim 3, further comprising a transparent encapsulating material layer covering at least the light emitting surface on which the fine pattern for light extraction is disposed.

17. The semiconductor light emitting device of claim 16, wherein the encapsulating material layer has a refractive index which is equal to or less than that of the second material layer.

18. The semiconductor light emitting device of claim 1, wherein the semiconductor light emitting structure comprises a nitride semiconductor layer.
